(19) United States
(12) Patent Application Publication
(10) Pub. No.: US 2021/0102696 A1
(43) Pub. Date: Apr. 8, 2021

(54) WATERPROOF LIGHTING POWER SUPPLY SYSTEM

(71) Applicant: Aion LED, Inc., San Francisco, CA (US)

(72) Inventor: Ryan P. Hanslip, San Francisco, CA (US)

(73) Assignee: Aion LED, Inc., San Francisco, CA (US)

(21) Appl. No.: 17/061,031

(22) Filed: Oct. 1, 2020

Related U.S. Application Data
(60) Provisional application No. 62/909,964, filed on Oct. 3, 2019.

(51) Int. Cl. F21V 31/00; F21V 23/00; F21V 23/06

(52) U.S. Cl. CPC F21V 31/005; F21Y 2115/10; F21V 23/06; F21V 23/007

(57) ABSTRACT

Systems and methods for waterproof lighting power supplies. The lighting power supply is waterproof to protect against environmental conditions inherent in certain environments, to include surface mounting and subterranean environments, where moisture or other contaminants may be present. In one feature, the power supply may include a ruggedized stainless steel or other metal cover. The waterproof lighting power supply may power light emitting diodes (LED) lighting systems, such as LED-based dimming systems that provide dynamic white and/or warm dimming features. In some embodiments, the waterproof lighting power supply is adapted to integrate with a warm dimming security light system.

### CROSS-REFERENCE TO RELATED APPLICATION

This application is a nonprovisional patent application of and claims the benefit of U.S. Provisional Patent Application No. 62/909,964, filed Oct. 3, 2019 and titled “Subterranean Lighting Power Supply,” the disclosure of which is hereby incorporated herein by reference in its entirety.

### FIELD

The disclosure relates generally to systems and methods involving waterproof lighting supply systems, and specifically to waterproof surface mounted or subterranean power supply systems used to power or drive light emitting diodes (LED) lighting.

### BACKGROUND

Conventional power supplies are subject to malfunction or failure when subjected to moisture or other contaminants and thus cannot be buried directly into the Earth because the power supplies would degrade and typically malfunction. Many lighting applications would benefit from a waterproof power supply that may be directly buried or surface mounted. For example, a waterproof power supply could be located closer to lighting fixtures and thus reduce electrical cabling connection requirements for lighting physically connected to a power supply or reduce power requirements for lighting connected through wireless systems. What is needed is a system and method of use that provides a waterproof lighting power supply.

The disclosure solves this need by providing a waterproof lighting power supply which is protected from environmental conditions inherent in direct burial, such as moisture conditions, by providing a waterproof lighting power supply. The waterproof lighting power supply may comprise a ruggedized stainless steel cover. In some embodiments, the waterproof lighting power supply is adapted to integrate with LED-based dimming systems, to include, for example, LED-based systems that provide dynamic white and/or warm dimming features, such as provided by a defined internal dim curve or one or more dim curves provided by a third party. In some embodiments, the waterproof lighting power supply is adapted to integrate with a warm dimming security light system.

### SUMMARY

Systems and methods for waterproof lighting power supplies. The waterproof lighting power supply is waterproof to protect against environmental conditions inherent in direct burial or other applications such as surface mounting where moisture conditions may exist and may include a ruggedized stainless steel cover. The waterproof lighting power supply may power light emitting diodes (LED) lighting systems, such as LED-based dimming systems that provide dynamic white and/or warm dimming features. In some embodiments, the waterproof lighting power supply is adapted to integrate with a warm dimming security light system.

In one embodiment, a waterproof power supply system is disclosed, the waterproof power supply system comprising: a body comprising a set of body sidewalls and a body bottom, the set of body sidewalls connected to the body bottom and collectively defining a body interior; a body cover adapted to form a secure and waterproof seal when engaged with the set of body sidewalls and completely enclose the body interior; an LED driver sized to fit within the body interior; at least one electrical input connector in electrical communication with the LED driver; and at least one electrical output connector in electrical communication with the LED driver; wherein: the waterproof power supply system maintains the LED driver in a waterproof environment when exposed to moisture conditions.

In one aspect, the body cover and the body are of a stainless steel material. In another aspect, the waterproof power supply system further comprises a protected circuit breaker in electrical communication with the LED driver. In another aspect, the at least one electrical output connector comprises a 24 volt output tap. In another aspect, the at least one electrical input connector is a liquid-tight conduit connector. In another aspect, the at least one electrical input connector operates to receive at least one of 120, 240, and 277 VAC. In another aspect, the waterproof power supply system further comprises a dimming module in communication with the LED driver and configured to operate a set of LED lights. In another aspect, the set of LED lights comprise a dynamic white LED. In another aspect, the dimming module operates to provide warm dimming to the set of LED lights. In another aspect, the dimming module is a Dynamic Tuner Module. In another aspect, the set of LED lights comprise a two channel LED light and a four channel LED light. In another aspect, the set of LED lights comprise a multiple colored LED. In another aspect, the set of LEDs form at least part of a security lighting system.

In another embodiment, a method of using a waterproof power supply system is disclosed, the method comprising: providing a waterproof power supply system comprising: a body comprising a set of body sidewalls and a body bottom, the set of body sidewalls connected to the body bottom and collectively defining a body interior; a body cover adapted to form a secure and waterproof seal when engaged with the set of body sidewalls and completely enclose the body interior; an LED driver sized to fit within the body interior; at least one electrical input connector in electrical communication with the LED driver; and at least one electrical output connector in electrical communication with the LED driver; connecting the LED driver with an AC power input source; connecting the LED driver with a set of LED lights; disposing the waterproof power supply system in a moisture environment; operating the set of LED lights with the waterproof power supply system; and maintaining the LED driver in a waterproof environment while exposed to a moisture environment.

In one aspect, the LED driver is connected with an AC power input source by way of the at least one electrical input connector. In another aspect, the AC power source is one of 120 VAC, 240 VAC, and 277 VAC. In another aspect, the LED driver is connected with a set of LED lights by way of the at least one electrical output connector. In another aspect, the LED driver outputs 24 VDC to operate the set of LED lights. In another aspect, the set of LEDs form at least part of a security lighting system.

In yet another embodiment, a waterproof power supply system is disclosed, the waterproof power supply system comprising: a body comprising a set of at least four sidewalls and a body bottom, the set of at least four body sidewalls connected to the body bottom and collectively defining a body interior; a body cover adapted to form a secure and waterproof seal when engaged with the set of at least four body sidewalls and completely enclose the body interior; an LED driver disposed within the body interior; an electrical input connector in electrically connected with the LED driver; an electrical output connector in electrically connected with the LED driver; and a protected circuit breaker in electrically connected with the LED driver, the electrical input connector, and the electrical output connector; wherein: the body cover and the body are of a stainless steel material; the electrical input connector operates to receive at least one of 120, 240, and 277 VAC; the electrical output connector comprises a 24 volt output tap; and the LED waterproof power supply system maintains the LED driver in a waterproof environment when exposed to a moisture environment.

By way of providing additional background, context, and to further satisfy the written description requirements of 35 U.S.C. § 112, the following references are incorporated by reference in their entireties (all to Hanslip): U.S. Pat. Nos. 10,378,747 and 10,663,156; and U.S. patent application Ser. Nos. 16/882,583; 16/537,285; 16/509,173; and 16/912,829.

Elements described in these references may be used or applied in the system and method of the disclosure. The phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising”, “including”, and “having” can be used interchangeably. The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material”.

The terms “determine”, “calculate” and “compute,” and variations thereof, as used herein, are used interchangeably and include any type of methodology, process, mathematical operation or technique.

The term “means” as used herein shall be given its broadest possible interpretation in accordance with 35 U. S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary, brief description of the drawings, detailed description, abstract, and claims themselves.

The term “waterproof” means impervious to water.

The term “watertight” means closely sealed, fastened, or fitted so that no water enters or passes through.

The phrase “water resistant” means able to resist the penetration of water to some degree but not entirely.

The phrase “moisture environment” means an environment in which moisture is present to an extent that entry into a conventional enclosure is likely.

The term “stainless steel” means any of the family of iron-based alloys that contain at least 11% chromium such that iron is prevented or highly resistant to rusting.

The preceding is a simplified summary of the disclosure to provide an understanding of some aspects of the disclosure. This summary is neither an extensive nor exhaustive overview of the disclosure and its various aspects, embodiments, and/or configurations. It is intended neither to identify key or critical elements of the disclosure nor to delineate the scope of the disclosure but to present selected concepts of the disclosure in a simplified form as an introduction to the more detailed description presented below. As will be appreciated, other aspects, embodiments, and/or configurations of the disclosure are possible utilizing, alone or in combination, one or more of the features set forth above or described in detail below. Also, while the disclosure is presented in terms of exemplary embodiments, it should be appreciated that individual aspects of the disclosure can be separately claimed.

### BRIEF DESCRIPTION OF THE DRAWINGS

The disclosure will be readily understood by the following detailed description in conjunction with the accompanying drawings, wherein like reference numerals designate like elements. The elements of the drawings are not necessarily to scale relative to each other. Identical reference numerals have been used, where possible, to designate identical features that are common to the figures.

FIG. 1A is a perspective view of one embodiment of the waterproof lighting power supply system of the disclosure;

FIG. 1B is a cross-sectional top-view of the waterproof lighting power supply system of FIG. 1A;

FIG. 2 is a schematic diagram of one embodiment of the waterproof lighting power supply system of FIGS. 1A-B engaged with a sensor, DTM, and set of LEDs;

FIG. 3 is a schematic diagram of one embodiment of a set of two waterproof lighting power supply systems engaged with a dimmer and 2 channel LED light fixture; and

FIG. 4 is a flow chart of one method of use of the waterproof lighting power supply system of FIGS. 1A-B.

### DETAILED DESCRIPTION

Reference will now be made in detail to representative embodiments. The following descriptions are not intended to limit the embodiments to one preferred embodiment. To the contrary, it is intended to cover alternatives, modifications, and equivalents as can be included within the spirit and scope of the described embodiments as defined, for example, by the appended claims.

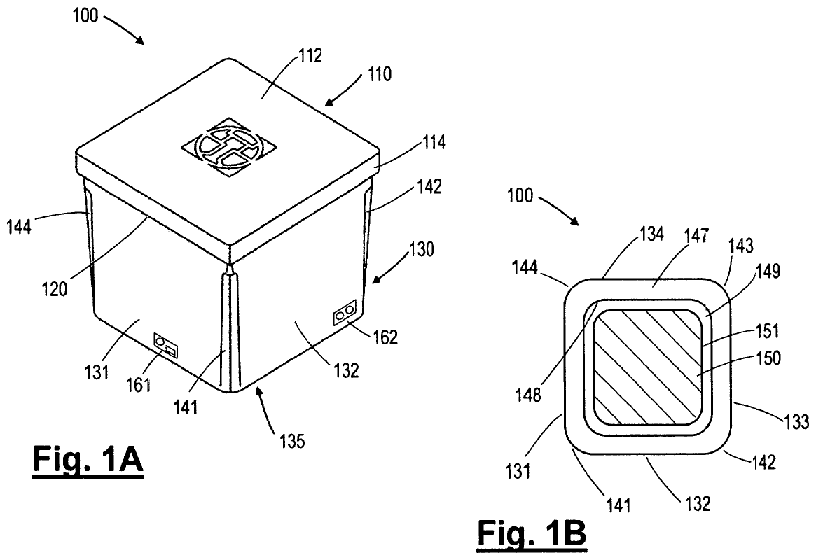

The disclosed devices, systems, and methods of use will be described with reference to FIGS. 1-4. Generally, systems and methods involving waterproof lighting power supplies are disclosed. The waterproof lighting power supply system is used to power or drive light emitting diodes (LED) lighting.

The waterproof lighting power supply system may be variously referred to as “waterproof power supply system,” “power supply system,” “waterproof lighting driver system,” and “system.” The method of use of the waterproof lighting power supply system may be referred to as “method.”

Generally, LEDs require LED drivers to regulate power to one or more LEDs. An LED driver, also referred to as an LED power supply, converts incoming or received Alternating Current (AC) power to Direct Current (DC) power to drive or power one or more LEDs. The LED driver also maintains power delivered to one or more LEDs to LED operating specifications, such as to within LED voltage specifications.

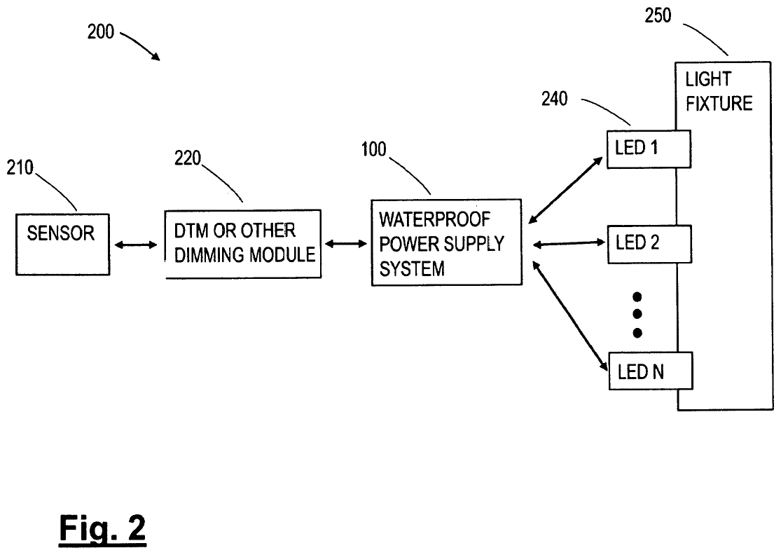

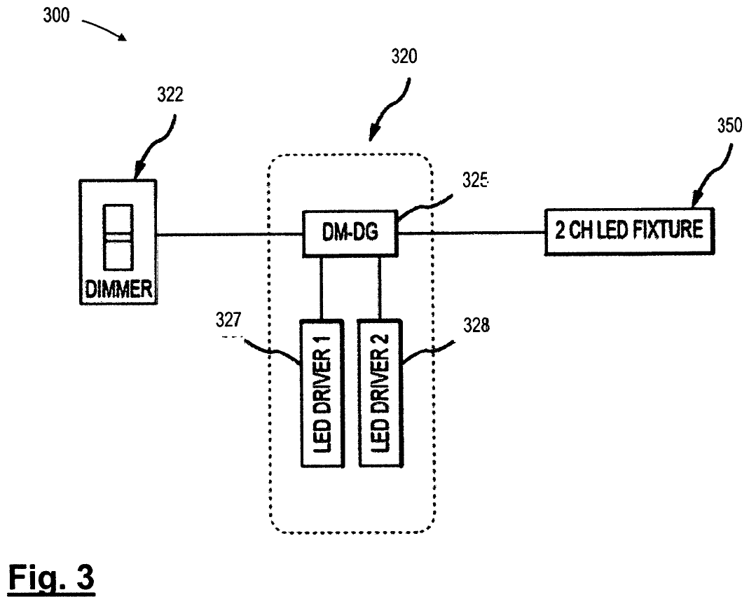

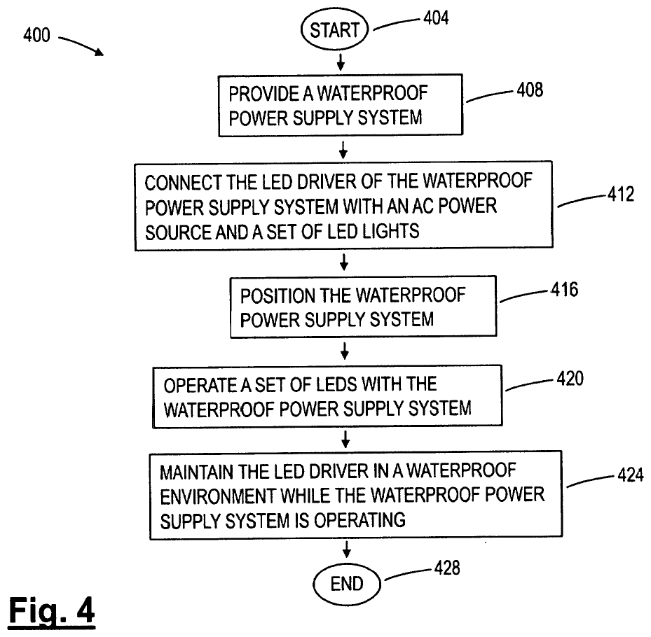

FIGS. 1A-B describe one embodiment of the waterproof lighting power supply system 100. FIG. 2 describes the waterproof lighting power supply system 100 of FIGS. 1A-B engaged with a sensor, DTM, and set of LEDs. FIG. 3 describes a set of two waterproof lighting power supply systems engaged with a dimmer and 2 channel LED light fixture. FIG. 4 describes a method of use of the waterproof lighting power supply system of FIGS. 1A-B.

With attention to FIGS. 1A-B, a waterproof lighting power supply system 100 is depicted. FIG. 1A is a perspective view of the waterproof lighting power supply system 100 and FIG. 1B is a cross-sectional top view of the waterproof lighting power supply system 100 taken at mid-section of the waterproof lighting power supply system 100 along a plane parallel to the cover 110 of the waterproof lighting power supply system 100.

The waterproof lighting power supply system 100 comprises a body 130 and a body cover 110. The body 130 comprises a set of body sidewalls rigidly connected to a body bottom 135 which collectively or in totality define a body interior 149. The body sidewalls comprise a set of body sidewalls: first body sidewall 131, second body sidewall 132, third body sidewall 133, and fourth body sidewall 134 (collectively, the “set of body sidewalls”). Each of the set of sidewalls have an upper portion and a lower portion; each of the upper portions detachably engage with the body cover 110 and each of the lower portions rigidly (or permanently) engage with the body bottom 135. The set of four body sidewalls collectively engage the body cover 110 to form body seal 120. When the set of four body sidewalls 131, 132, 133, 134 (as engaged or permanently attached to body bottom 135) are engaged with the detachable body cover 110 to form body seal 120, the body interior 149 defines a completely enclosed body interior 149. Stated another way, the body bottom 135 and the set of four body sidewalls 131, 132, 133, 134 when engaged with the body cover 110 to form body seal 120, the body interior 149 is completely enclosed.

When the body interior 149 is completely enclosed, the body interior 149 maintains or presents a watertight environment, a waterproof environment, and/or a water-resistant environment.

Other configurations of the set of body sidewalls are possible. For example, the set of sidewalls may vary in number, geometry, and/or orientation. In the embodiment of FIGS. 1A-B, the set of body sidewalls are four in number, are each of the same geometry, and are generally of vertical orientation relative to the horizontal orientation of the body bottom 135. In some embodiments, the sidewalls number other than four, such as three or five or six or any number so as to allow the complete enclosure of the body interior 149 when the set of body walls form a body seal 120 with the body cover 110. Similarly, the body cover 110 may be configured in other than the square shape of FIGS. 1A-B so as to conform to the geometry presented by the set of body walls. For example, in a configuration of the waterproof lighting power supply system 100 with a set of three identical body walls, the body cover 110 would form a triangle shape to engage with the set of three body walls. In some embodiments, one or more body walls are other than of generally vertical orientation relative to the horizontal orientation of the body bottom 135, e.g. one or more body walls may present a tilt inwards or outwards relative to a direction from the body bottom 135 toward the body cover 110. In one embodiment, the set of body walls are tilted outwards from the body bottom 135 toward the body cover 110 to facilitate burial of the waterproof lighting power supply system 100.

The body cover 110 of the embodiment of FIGS. 1A-B is depicted overlapping the set of edges of the upper portion of the set of body sidewalls 131, 132, 133, 134 to form body seal 120. Other configurations of the engagement or attachment of the detachable body cover 110 with the set of body sidewalls are possible, such as the body cover 110 fitting to an interior of the set of body sidewalls. With attention to FIG. 1B, the set of sidewalls 131, 132, 133, 134 form a body thickness 147 with body exterior surface and body interior surface 148. The body interior surface 148 forms a perimeter about or around the body interior 149. In the aforementioned body cover configuration wherein the body cover 110 engages with an interior of the set of body sidewalls, the body cover 110 engages with the body interior surface 148. The body interior surface 148 may be fitted with a lip to engage the body cover 110. The body cover 110 may engage with the upper portions of the set of body sidewalls by way of an interference fit and/or with aid of a gasket or seal, such as a rubberized gasket or rubberized seal fitted between the upper portions of the set of body sidewalls and the body cover 110, such a gasket or seal enabling or assisting in providing a watertight environment, a waterproof environment, and/or a water-resistant environment to the body interior 149.

The body cover 110 may be comprised of stainless steel or any material known to those skilled in the art to be rust resistant or otherwise retard rust. The body cover may be grime resistant or be a grime-over body cover. The body cover 110 may be a ruggedized stainless steel cover and/or a ruggedized metal cover plate

The set of body sidewalls 131, 132, 133, 134 create a set of body exterior edges 141, 142, 143, 144. First body exterior edge 141 is formed at the juncture or intersection of first body sidewall 131 and second body sidewall 132. Second body exterior edge 142 is formed at the juncture or intersection of second body sidewall 132 and third body sidewall 133. Third body exterior edge 143 is formed at the juncture or intersection of third body sidewall 133 and fourth body sidewall 134. And fourth body exterior edge 144 is formed at the juncture or intersection of fourth body sidewall 134 and first body sidewall 131. One or more of the body exterior edges 141, 142, 143, 144 may comprise additional thickness, additional sealing, or other measures known to those skilled in the art to maintain a waterproof environment, a waterproof environment, and/or a water-resistant environment to the body interior 149.

The body interior 149 of the waterproof lighting power supply system 100 is configured or fitted to receive an LED driver 150, the LED driver 150 having an LED driver exterior 151. In one embodiment, as shown in FIG. 1B, the LED driver exterior 151 forms a gap or space with the body interior surface 148. Such a gap or space may allow for thermal expansion of the body interior space. In some embodiments, the LED driver exterior 151 does not form a gap or space with the body interior surface 148. In some embodiments, the LED driver exterior 151 forms an interference fit with the body interior surface 148.

The LED driver 150 may be operate or drive or power one or more LED lights. Stated another way, the LED driver 150 may operate or drive or power one or a set of LED lights. (For example, in FIG. 2 an LED driver 150 of the waterproof lighting power supply system 100 drives a set of N LEDs). The LED driver 150 of the waterproof lighting power supply system may operate or engage with one or more of dimmer controls, DTM (“dynamic tuner module”) or other dimming module(s), and/or controller(s), as described below. In one embodiment, the LED driver 150 of the waterproof lighting power supply system 100 may interact with LED systems that receive an external dimming curve, such as an external dimming curve provided by a third party, as described below. The LED driver 150 of the waterproof lighting power supply system may operate or engage with a warm dimming security lighting system, as described below. The LED driver 150 of the waterproof lighting power supply system may operate or engage with dynamic white, colored, multi-channel, color tuning, and/or warm dimming lighting systems and/or elements, as described below.

The waterproof lighting power supply system 100 further comprises an electrical input connector 161 disposed or positioned on the first body sidewall 131 and an electrical output connector 161 disposed or positioned on the second body sidewall 162. Each of the electrical input connector 161 and the electrical output connector 162 are electrically connected to or are in electrical communication with the LED driver 150. Each of the electrical input connector 161 and the electrical output connector 162 pass through the body thickness 147.

The electrical input connector 161 may be a liquid-tight conduit connector. The electrical input connector 161 may operate to receive one or more of standard AC power, to include 120 VAC, 240 VAC, and 277 VAC. In some embodiments, the electrical input connector 161 operates as a wireless connector. In some embodiments, the electrical input connector 161 is disposed on other than the first body sidewall 131. In some embodiments, the electrical input connector 161 is disposed on other than the first body sidewall 131, to include within the body, and on other locations other than a lower portion of a side wall, such as on a medial or upper portion of a side wall.

The electrical output connector 162 may be a liquid-tight conduit connector. The electrical output connector 162 may operate to supply or output one or more of standard DC power, to include 24 VDC. In some embodiments, the electrical output connector 162 operates as a wireless connector. In some embodiments, the electrical output connector 162 is disposed on other than the second body sidewall 132, to include within the body, and on other locations other than a lower portion of a side wall, such as on a medial or upper portion of a side wall.

In some embodiments, the waterproof lighting power supply system 100 may receive or transmit power to or from the LED driver 150 by wireless connections, thereby obviating the need to one or both of the electrical input connector 161 and the electrical output connector 162.

The waterproof lighting power supply system 100 may comprise a protected circuit breaker in electrical communication with the LED driver 150, the electrical input connector 161, and/or the electrical output connector 162.

In one embodiment, the waterproof lighting power supply system 100 may be of compact dimension, e.g. at or below 8 inch by 8 inch by 7 inch. In one embodiment, the waterproof lighting power supply system 100 is a solid state system.

In one embodiment, the waterproof lighting power supply system 100 is UL listed. In one embodiment, the waterproof lighting power supply system 100 satisfies and/or has approval of one or more IP or other codes or standards, such as IP68, EN 60529, and NEMA 6P requirements. The Ingress Protection (IP) Code rates the level of protection of a device enclosure to external intrusions such as dust, dirt, sand, and water, as is promulgated, maintained, and administered by the International Electrotechnical Commission (IEC). (The equivalent European standard to IP68 is EN 60529). Generally, an IP68 device enclosure will be protected from dust ingress and will be waterproof when submerged in water up to 1.5 m deep for 30 minutes.

In one embodiment, the power supply system is UL listed and/or UL recognized (UL is Underwriters Laboratories, an entity that tests and certifies products to safety standards). In one embodiment, the lighting power supply system is a class 2 electronic device and/or is fully potted.

In one embodiment, the waterproof lighting power supply system 100 conforms to Title 24 JA8 listing. In one embodiment, the waterproof lighting power supply system 100 is primarily or substantially made of stainless steel. In one embodiment, the body 130 and the body cover 110 of the waterproof lighting power supply system 100 is made of stainless steel. In one embodiment, the body 130 and the body cover 110 of the waterproof lighting power supply system 100 is made of a nonmetallic material, such as a plastic or rubber material. In one embodiment, the waterproof lighting power supply system 100 may be configured to produce an LED system that is timed as a function of circadian rhythms.

FIGS. 2 and 3 provide embodiments of the waterproof lighting power supply system 100 of FIGS. 1A-B as engaged with additional external elements, such as LED light dimmers, environmental sensors, and LED light fixtures.

Generally, the waterproof lighting power supply system 100 may be configured to drive, operate, or power a set of LEDs, the set of LEDs operating in an isolated manner or as part of a larger system, such as a security light system.

FIG. 2, the waterproof lighting power supply system 100 is depicted as operating or driving a set of LED lights 240, the set of LED lights 240 engaged or coupled or attached to a light fixture 250, and engaged with a DTM or other dimming module, the DTM engaged with a system sensor 210.

The warm dimming sensor lighting system (the “sensor lighting system”) 200 of FIG. 2 comprises one or more sensors 210, a DTM (“dynamic tuner module”) or other dimming control module 220 (also referred to as a “dimming controller” or simply a “controller”), the waterproof lighting power supply system 100, one or LEDs 240, and a lighting fixture 250. In one embodiment, the lighting fixture 250 is not a part of the sensor lighting system 200. In some embodiments, the one or more LEDs 240 may comprise other than LED lights, e.g. a halogen lamp and other lights known to those skilled in the art. In some embodiments, each LED 240 may be engaged with a separate lighting fixture 250. In some embodiments, one or more LEDs 240 may be driven or controlled by a separate waterproof lighting power supply system 100, the separate waterproof lighting power supply system 100 in communication with the DTM controller 220.

Generally, the sensor lighting system 200 smoothly changes one or more LED lights 240 according to a selectable set of LED configuration states, the states defined by, e.g., LED light temperature values, LED light distribution patterns, and other LED characteristics as known to those skilled in the art. For example, the set of LED lights may change from a dim warm white look to bright cool white flood light as triggered by sensor 210 measurements, such as, for example, the presence of an object within a defined security perimeter and as determined based on the distance to the object from the sensor 210. (This an example regarding a security light system, as described in U.S. patent application Ser. No. 16/930,006 to Ironfield, incorporated by reference in entirety for all purposes.)

The one or more sensors 210 may comprise a proximity or occupancy sensor which is triggered or senses an object, such as a person, at a selectable distance from the sensor 210, and/or senses an object, such as a person, is positioned at a selectable location. For example, the sensor 210 may trigger or sense or measure when an object is 10 m or less from the sensor, and/or when an object is occupying a selected position or location such as a front door of a residence. The sensor 210 may also trigger upon movement at a selected location, such as movement within a defined area surrounding a car parked near a residence or business.

The DTM or other dimming module (the “DTM”) 220 receives sensor data from the one or more sensors 210 and creates or controls dimming of one or more LEDs 240. For example, in one embodiment, the DTM 220 controls or drives a configurable dynamic LED white light 240 so as to smoothly change the light 240 from a dim warm white look to a bright cool white flood light. Other dimming control schemes are possible. For example, the DTM 220 may adjust or control or drive one or more LEDs 340 per any provided “dim curve” to include dim curves provided by way of, e.g., externally-provided dim curves, electronic input such as by way of an app and/or a smart phone, and the like. The use of dim curves is described in U.S. Pat. Nos. 10,111,294 and 10,383,189, and U.S. patent application Ser. No. 16/537,285, each to Hanslip and each incorporated by reference in entirety for all purposes.)

The DTM 220 is a network device that can communicate with lighting controls and fixtures via a network router. DTM 220 may also link to an iOS or Android-type device over WI-FI or blue tooth, putting the power to configure, control and customize intensity, color and color temperature of white lighting usable at a user device, such as a smartphone. Thus, the DTM 220 may simplify and automate the process of creating the warm-dimming effect by storing multi-channel dim curves on a microprocessor and memory (not shown) that may store the dim curves (and other selectable characteristics of the one or more LED lights 240) and can be activated by a standard wall box dimmer (322 in FIG. 3, as discussed below). The microprocessor may be a part of the DTM or the power supply system 100. This driver simplifies wiring, installation and saves cost and eliminates the DMX and DMX drivers required with a conventional DTM solution. This may also allow the controller 220 to communicate directly with any drivers associated with the one or more LEDs 340, and provide the functionality to receive the binary communication from the third party control, and change and or augment the communication to change the control information and thereby change the functionality of the drivers of the one or more LEDs 240.

Waterproof lighting power supply system 100 provides power to one or more LEDs 240, DTM 230, and/or sensors 210.

The one or more LEDs 240 may be, in various embodiments, any combination of round or linear, 2 or 4 channel LED lights, with multiple colored diodes. In an example, fixtures 250 may include a red, green, blue, and white LED source or module.

The one or more LEDs 240 may be coupled with or be disposed on a light fixture 250. In one embodiment, the light fixture 250 forms at least a part of a security system light fixture, such as mounted on business or residential structures. The light fixture 250 may be any light fixture known to those skilled in the art, to include light fixtures used in security applications.

A user device (not shown) may be configured with one or more applications (the “app”), such as an iOS application, that engages with the DTM controller 220. The app allows for network triggers to be created on the Dynamic Tuner Module 220 so that it can listen for network traffic on specific ports and/or IP addresses with specific strings. Depending on the received string, it can perform simple commands, such as activating a specified preset. Network triggers are particularly useful so that third party devices can issue commands that Dynamic Tuner Module 220 responds to in the same way that it responds to the app's simple commands.

On setup completion, the app's home screen may be displayed on the user device with buttons that mirror the layout of button wall panels used in similar systems. Each button can be edited to write a custom preset functionality to the Dynamic Tuner Module 220 from the app that can be operated later without the use of the app. Once the preset is defined and saved to the Dynamic Tuner Module 220, only simple commands are needed from the app, wall panel, or network trigger to activate the complex logic that manages button presets.

All of the independent and integrated functionality is created from within the app so that it can configure Dynamic Tuner Module 220 to listen to third party commands, manage dimming, dim level recall, active sundial states, active color, and cycle speeds behind the various preset modes. Another configuration of DTM controller components is provided as FIG. 3, described in more detail below.

The sensor lighting system 200 includes software interface as well as the LED systems and associated dimming levels and methods utilized to create full-spectrum color-tuning lighting systems that can reproduce accurate, high quality lighting.

A communication network (not shown) connects the elements of the sensor lighting system 200, and may include the Internet, cellular, Wi-Fi, blue-tooth, satellite, radio frequency (RF), or any other form of wires or wireless communication network between, e.g. fixtures 250, LED control drivers (not shown) controlling the fixtures and/or LED lights 240, controller 220, sensor 210, and remote user device which may control or otherwise engage with sensor lighting system 200 elements and may include cloud-type programs and devices. User device(s) may include smart phones, tablets, or any other device capable of sending and receiving information to the various elements of sensor lighting system 200. The information may include information associated with lighting control, configuration information, and information about the system elements, to include particular configurations of the one or more LED lights 240, a security perimeter definition, or other information. The communication between sensor lighting system 200 elements may be wired or wireless.

In one embodiment, the waterproof lighting power supply system 100 and/or the sensor lighting system 200 operate such that unique dynamic white lighting techniques and DTM technology are employed to leverage efficient variable cool to warm white dim curves that may be accessed at any point on the (dimming) curve to reproduce the desired lighting color temperature and intensity with repeatable results.

FIG. 3 is a schematic diagram of one embodiment of a set of two waterproof lighting power supply systems 327, 328 forming a 2 channel LED fixture system 300.

The 2 channel LED fixture system 300 comprises a DTM 320, the DTM 320 comprising a dimming module 325 and two waterproof lighting power supply systems 327, 328. Each of the two waterproof lighting power supply systems 327, 328 are similar to those described above, such as described with respect to FIGS. 1A-B. The dimming module 325 may store one or more dim curves, to include those of third parties. In one embodiment, waterproof lighting power supply system 327 (identified as “LED Driver 1” in FIG. 3) is a cool LED and the waterproof lighting power supply system 328 (identified as “LED Driver 2” in FIG. 3) is a warm LED, and the DTM 320 includes no DMX and thus requires no programming. The DTM 320 is configured to engage a standard dimmer 322, such as a 0-10V dimmer, and to engage a two channel LED fixture 350, such as a cool/warm two channel LED fixture. The 2 channel LED fixture system 300 thus may provide warm dim and dynamic white lighting effects.

FIG. 4 provides a flow diagram of one method of use 400 of the embodiment of the waterproof lighting power supply system of FIGS. 1A-B. However, aspects and features of any of the FIGS. 1-3 may be referenced to enhance the disclosure of the method of use.

Generally, the method 400 starts at step 404 and ends at step 428. Any of the steps, functions, and operations discussed herein can be performed continuously and automatically. In some embodiments, one or more of the steps of the method of use 400, to include steps of the method 400, may comprise computer control, use of computer processors, and/or some level of automation. Indeed, most of the steps of method 400 are performed automatically. However, in some embodiments some of the steps or parts of some of the steps are performed in concert with or exclusively by human intervention. For example, the operation of the set of LEDs of step 420 may involve human interaction via, e.g., a display/GUI.

The steps are notionally followed in increasing numerical sequence, although, in some embodiments, some steps may be omitted, some steps added, and the steps may follow other than increasing numerical order. A user may interact or perform one or more of the described steps be using a display/GUI. The phrase “user interface” or “UI”, and the phrase “graphical user interface” or “GUI”, means a computer-based display that allows interaction with a user with aid of images or graphics.

After starting at step 404, the method 400 proceeds to step 408. At step 408, a waterproof lighting power supply system is provided, of the type described above, such as with respect to FIGS. 1A-B. After completion of step 408, the method 400 proceeds to step 412.

At step 412, the LED driver 150 of the waterproof lighting power supply system 100 is connected with an AC power source and also connected with one or more LEDs, such as a set of LEDs. The connection may be physical and/or wireless. The connection between the LED driver 150 and the AC power source may be by way of one or more electrical input connectors 161. The connection between the LED driver 150 and the one or more LED lights may be by way of one or more electrical output connectors 162. After completion of step 412, the method 400 proceeds to step 416.

At step 416, the waterproof lighting power supply system 100 is positioned in a moisture environment, such as buried underground aka buried beneath or substantial below the Earth, surface mounted yet exposed to moisture, or any combination thereof. In one embodiment, the waterproof power supply system is positioned in any position that may expose the system to moisture or contaminants, to include near or adjacent a pool or jacuzzi, whether indoor or outdoor. After completion of step 416, the method 400 proceeds to step 420.

At step 420, the waterproof lighting power supply system 100 operates or powers or drives the set of LED lights. After completion of step 420, the method 400 proceeds to step 424.

At step 424, the waterproof lighting power supply system 100 maintains the enclosed LED driver 150 in a waterproof environment while the waterproof lighting power supply system 100 is exposed to moisture and/or other contaminants. After completion of step 424, the method 400 ends at step 428.

The exemplary systems and methods of this disclosure have been described in relation to systems and methods involving a waterproof lighting power supply system. However, to avoid unnecessarily obscuring the present disclosure, the preceding description omits a number of known structures and devices, and other application and embodiments. This omission is not to be construed as a limitation of the scopes of the claims. Specific details are set forth to provide an understanding of the present disclosure. It should however be appreciated that the present disclosure may be practiced in a variety of ways beyond the specific detail set forth herein.

A number of variations and modifications of the disclosure can be used. It would be possible to provide for some features of the disclosure without providing others.

Although the present disclosure describes components and functions implemented in the aspects, embodiments, and/or configurations with reference to particular standards and protocols, the aspects, embodiments, and/or configurations are not limited to such standards and protocols. Other similar standards and protocols not mentioned herein are in existence and are considered to be included in the present disclosure. Moreover, the standards and protocols mentioned herein, and other similar standards and protocols not mentioned herein are periodically superseded by faster or more effective equivalents having essentially the same functions. Such replacement standards and protocols having the same functions are considered equivalents included in the present disclosure.

The present disclosure, in various aspects, embodiments, and/or configurations, includes components, methods, processes, systems and/or apparatus substantially as depicted and described herein, including various aspects, embodiments, configurations embodiments, sub-combinations, and/or subsets thereof. Those of skill in the art will understand how to make and use the disclosed aspects, embodiments, and/or configurations after understanding the present disclosure. The present disclosure, in various aspects, embodiments, and/or configurations, includes providing devices and processes in the absence of items not depicted and/or described herein or in various aspects, embodiments, and/or configurations hereof, including in the absence of such items as may have been used in previous devices or processes, e.g., for improving performance, achieving ease and\or reducing cost of implementation.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as a separate preferred embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A waterproof power supply system comprising:
a body comprising a set of body sidewalls and a body bottom, the set of body sidewalls connected to the body bottom and collectively defining a body interior;
a body cover adapted to form a secure and waterproof seal when engaged with the set of body sidewalls and completely enclose the body interior;
an LED driver sized to fit within the body interior;
at least one electrical input connector in electrical communication with the LED driver; and
at least one electrical output connector in electrical communication with the LED driver; wherein:
the waterproof power supply system maintains the LED driver in a waterproof environment when exposed to moisture conditions.

2. The waterproof power supply system of claim 1, wherein the body cover and the body are of a stainless steel material.

3. The waterproof power supply system of claim 1, further comprising a protected circuit breaker in electrical communication with the LED driver.

4. The waterproof power supply system of claim 1, wherein the at least one electrical output connector comprises a 24 volt output tap.

5. The waterproof power supply system of claim 1, wherein the at least one electrical input connector is a liquid-tight conduit connector.

6. The waterproof power supply system of claim 1, wherein the at least one electrical input connector operates to receive at least one of 120, 240, and 277 VAC.

7. The waterproof power supply system of claim 1, further comprising a dimming module in communication with the LED driver and configured to operate a set of LED lights.

8. The waterproof power supply system of claim 7, wherein the set of LED lights comprise a dynamic white LED.

9. The waterproof power supply system of claim 7, wherein the dimming module operates to provide warm dimming to the set of LED lights.

10. The waterproof power supply system of claim 7, wherein the dimming module is a Dynamic Tuner Module.

11. The waterproof power supply system of claim 7, wherein the set of LED lights comprise a two channel LED light and a four channel LED light.

12. The waterproof power supply system of claim 7, wherein the set of LED lights comprise a multiple colored LED.

13. The power supply system of claim 7, wherein the set of LEDs form at least part of a security lighting system.

14. A method of using a waterproof power supply system, the method comprising:
providing a waterproof power supply system comprising:
a body comprising a set of body sidewalls and a body bottom, the set of body sidewalls connected to the body bottom and collectively defining a body interior;
a body cover adapted to form a secure and waterproof seal when engaged with the set of body sidewalls and completely enclose the body interior;
an LED driver sized to fit within the body interior;
at least one electrical input connector in electrical communication with the LED driver; and
at least one electrical output connector in electrical communication with the LED driver;
connecting the LED driver with an AC power input source;
connecting the LED driver with a set of LED lights;
disposing the waterproof power supply system in a moisture environment;
operating the set of LED lights with the waterproof power supply system; and
maintaining the LED driver in a waterproof environment while exposed to a moisture environment.

15. The method of claim 14, wherein the LED driver is connected with an AC power input source by way of the at least one electrical input connector.

16. The method of claim 15, wherein the AC power source is one of 120 VAC, 240 VAC, and 277 VAC.

17. The method of claim 14, wherein the LED driver is connected with a set of LED lights by way of the at least one electrical output connector.

18. The method of claim 17, wherein the LED driver outputs 24 VDC to operate the set of LED lights.

19. The method of claim 11, wherein the set of LEDs form at least part of a security lighting system.

20. A waterproof power supply system comprising:
a body comprising a set of at least four sidewalls and a body bottom, the set of at least four body sidewalls connected to the body bottom and collectively defining a body interior;
a body cover adapted to form a secure and waterproof seal when engaged with the set of at least four body sidewalls and completely enclose the body interior;
an LED driver disposed within the body interior;
an electrical input connector in electrically connected with the LED driver;
an electrical output connector in electrically connected with the LED driver; and
a protected circuit breaker in electrically connected with the LED driver, the electrical input connector, and the electrical output connector;
wherein:
the body cover and the body are of a stainless steel material;
the electrical input connector operates to receive at least one of 120, 240, and 277 VAC;
the electrical output connector comprises a 24 volt output tap; and
the LED waterproof power supply system maintains the LED driver in a waterproof environment when exposed to a moisture environment.
